(19) United States
(12) Patent Application Publication
(10) Pub. No.: US 2004/0129958 A1
(43) Pub. Date: Jul. 8, 2004

(54) Compact microwave/millimeter wave filter and method of manufacturing and designing thereof

(76) Inventors: Philip J. Koh, Centreville, VA (US); David T Nemeth, Washington, DC (US); Steven M Marazita, Charlottesville, VA (US)

Correspondence Address: SUGHRUE MION, PLLC, 2100 PENNSYLVANIA AVENUE, N.W., SUITE 800, WASHINGTON, DC, 20037, US

(21) Appl. No.: 10/469,919

(22) PCT Filed: Mar. 8, 2002
(86) PCT No.: PCT/US02/07051

(51) Int. Cl. H01L 29/80

(52) U.S. Cl. 257/275

(57) ABSTRACT

A filter has suspended metal structures which are surrounded by a metal shield on all sides, except at the input and output ports. The shape of the metal determines the type of filter. The signal can be coupled into and out of the filter either by coplanar waveguide ports, stripline ports, or through a waveguide connection. The metals making up the filters are suspended, and only come into contact with air or with an extremely thin dielectric. This minimizes both dielectric losses and ohmic losses in the metal, and allows filters to be made without separately mounted dielectric resonators. The low losses allows, in the cause of a bandpass filter, high Q resonators to be achieved, thus providing a high quality filter with low insertion loss in the passband.

This application claims priority from the following U.S. Provisional Applications: No. 60/274,108, filed Mar. 8, 2001; No. 60/283,292 filed Apr. 12, 2001; No. 60/289,332 filed May 7, 2001; and No. 60/292,348 filed May 21, 2001. The contents of these provisional applications are incorporated herein by reference.

### FIELD OF THE INVENTION

The present invention relates to a compact, low cost per unit millimeter wave or microwave filter.

### DESCRIPTION OF THE RELATED ART

For numerous applications, including wide bandwidth communications, there is a need to use high frequency electromagnetic waves in the upper microwave and millimeter wave range. One common component in such systems is the filter, which is used to pass one set of frequencies while rejecting another. There is a need for pre-made, surface mountable components that can be provided at low cost. There is also a market for filters with waveguide connections. The present invention can be mounted in a housing to provide a light weight, low cost filter with waveguide connections. It can also be used as a compact surface mounted component.

### SUMMARY OF THE INVENTION

An object of the present invention is to provide a microwave/millimeter wave filter that can be mass produced at low cost per unit.

In order to accomplish this object, the present invention provides a filter which has suspended metal structures which are surrounded by a metal shield on all sides, except at the input and output ports. The shape of the metal determines the type of filter. For example, two coupled metal resonators can be made to form a bandpass filter. Other structures can be used to form low pass, high pass, or band-reject filters. The invention is produced using standard micromachining techniques. A means for coupling a signal in and out is provided. The signal can be coupled into and out of the filter either by coplanar waveguide ports, stripline ports, a slotline ports, or through a waveguide connection.

The metal making up the filters are suspended, and only come into contact with air or with an extremely thin dielectric. This minimizes both dielectric losses and ohmic losses in the metal. This allows filters to be made without separately mounted dielectric resonators. The filters can be made in a completely batch process.

The low losses allows, in the case of a bandpass filter, high Q resonators to be achieved, thus providing a high quality filter with low insertion loss in the passband.

The invention is constructed using standard micromachining techniques. It is produced by lithographically creating the metallic structures on a silicon substrate, then removing the supporting silicon under the metallic structures. The silicon is removed by etching using an anisotropic silicon etch, which can be made to undercut structures on top of the silicon in a well controlled way.

### BRIEF DESCRIPTION OF THE DRAWINGS

FIGS. 1(a)-(h)—show an example of the cross section of a main wafer during the fabrication process according to the present invention.

FIGS. 2(a)-(d)—show examples of filter structures according to the present invention.

FIGS. 3(a)-(h)—show fabrication of the cap wafer according to the present invention.

FIGS. 4(a)-d)—show examples of convex corner protectors for the cap wafer layer according to the present invention.

FIG. 5—shows an example of a device according to the present invention as an exploded view thereof.

FIG. 6—shows an example of a completed device according to the present invention, wherein only the signal ports are visible from the outside.

FIGS. 7(a) and (b)—are an illustrative example of a novel design technique for designing filters according to the present invention.

### DESCRIPTION OF THE PREFERRED EMBODIMENTS

The fabrication of an embodiment of a band pass filter is described.

The fabrication starts with two high resistivity silicon wafers that are polished on both sides. The wafers have the <100> crystal planes parallel to the surface of the wafers. They are referred to as the cap wafer and the main wafer. Both wafers have a masking layer deposited or grown on both sides of the wafer. One embodiment uses a thermally grown silicon dioxide layer.

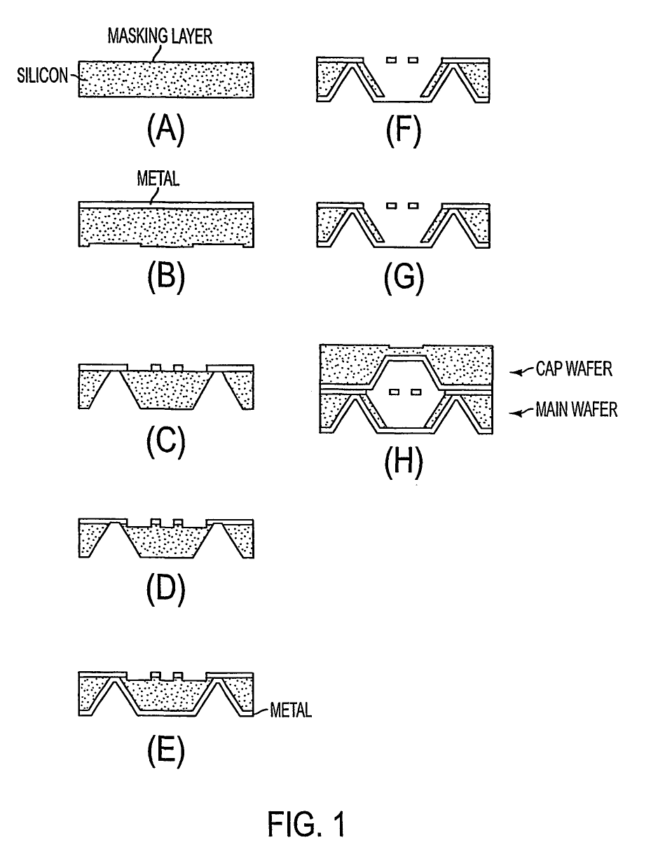

The main wafer is processed as shown in FIG. 1. FIG. 1a shows the wafer with a silicon dioxide layer. The next step is to put down a patterned layer of metal on one side of the wafer. For example, a seed layer of chrome and gold is evaporated on one side of the wafer. The wafer is then patterned with a photoresist mask, and electroplated with gold through the photoresist. The photomask is then stripped away. The seed layer can be patterned to act as a mask for a later stage in the process.

The mask layer on the back side is then patterned and etched. The patterning is done with standard photolithography, and the etch is any standard etch which is appropriate for the masking layer. For example, a thermally grown silicon dioxide layer can be etched through a photolithography mask with 10% hydrofluoric buffered oxide etch. The pattern on the back side is aligned to the metal pattern on the front side. The wafer now appears as in FIG. 1(b).

In the next step, the wafer is etched in an anisoptropic silicon etchant, for example 25% weight/weight tetramethylammonia hydroxide (TMAH) in water heated to 95 degrees Celsius. This will etch the silicon in the <100> direction, but only etch very slowly in the <111> direction. This will cause rectangle pits to form that go all the way through the wafer. The pattern is designed so the pits terminate underneath the thick metal layer. This is illustrated in FIG. 1(c). The thick metal layer will form a stretched membrane across the hole in the silicon.

The next step is an etch to remove the mask layer which is at the bottom of the etched pits. The mask layer on the bottom of the wafer does not need to be protected from the etch, as it serves no other function at this point. The masking layer at the top is patterned and etched at this stage as well. In an alternate process, the top is masked by the seed layer metal put down and patterned at an earlier step, eliminating the patterning step at this stage. The wafer now appears as in FIG. 1(d).

The bottom of the wafer is coated with thick metal at this stage, as in FIG. 1(e). This is done using some standard technique. One method, for example, is the evaporation of a seed layer of metal, followed by an electroplating step. Note that the metal deposited on the back forms a continuous contact with the metal on the top.

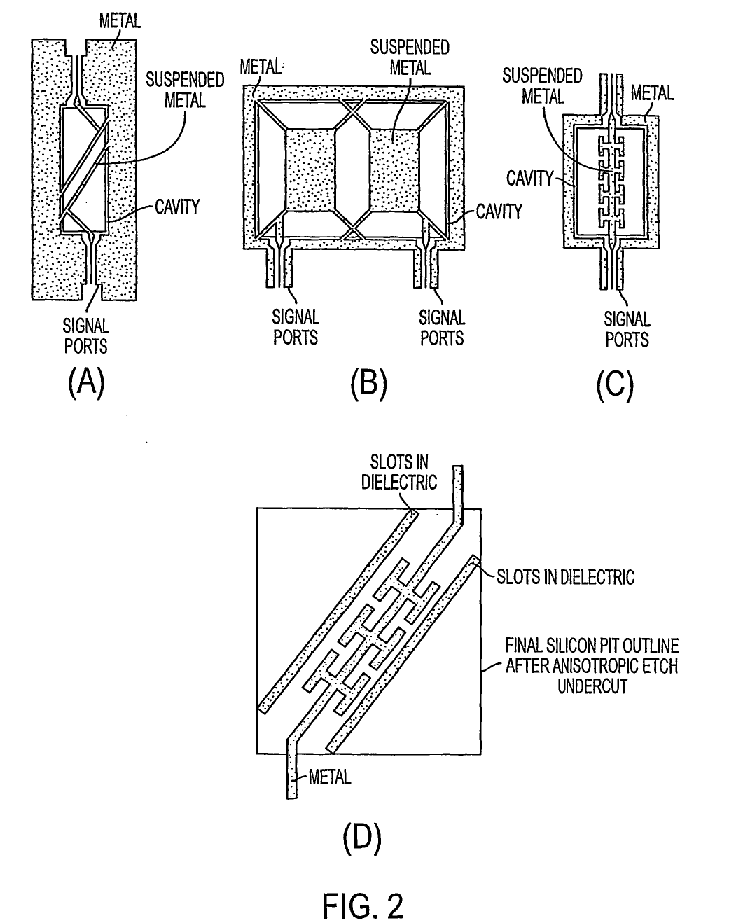

The wafer is then etched in anisotropic etchant again. The metal on the back side of the wafer protects it from the etchant. The etching on the front will undercut parts of the metal structure, leaving them suspended. This is illustrated in FIG. 1(f). Undercutting of the metal will occur in an anisotropic etchant if the metal pattern is correctly designed. Two examples of appropriate metal structures are shown in FIG. 2. Many others are possible. The conditions for undercutting masking patterns using anisotropic etches are well described in the literature.

A final step of removing the masking layer which is still attached to the bottom of the suspended metal is sometimes required. This is shown in FIG. 1(g). For example, if the masking layer is thermally grown silicon dioxide and the metal layer is 2.5 microns of electroplated gold, the suspended metal will curve because the silicon dioxide is compressively stressed. Etching the wafer in 10% Hydrofluoric acid buffered oxide etch will remove this oxide and cause the metal to flatten out.

An alternate embodiment replaces the oxide masking layer with a masking layer which is not etched away. For example, a low stress silicon nitride film is grown on the wafer. Holes are patterned in the silicon nitride in just a few places. The wafer is then etched in an isotropic etchant, leaving the nitride membrane suspended and supporting the metal lines. This has the advantage of allowing a larger range of metallic structures to be formed. For example, the low pass filter shown in FIG. 2(c) could not be made without a supporting membrane, because the ends of some of the metal lines would fold down.

Thus, FIG. 1, illustrates the cross section of a main wafer during the fabrication process according to an embodiment of the present invention. The process starts with a bare <100> high resistivity silicon wafer. The wafer has a masking layer, such as silicon oxide or silicon nitride grown on both sides, as seen in FIG. 1(a). Next, metal is deposited on the top side of the wafer and patterned. The masking layer is then patterned and etched on the back side, as shown in FIG. 1(b). The wafer is then etched in an anisotropic silicon etch (such as tetramethyl ammonium hydroxide) completely through the wafer, forming pyramidal pits, as seen in FIG. 1(c). The masking layer is then etched away, as shown in FIG. 1(d). Notice that the masking layer is completely removed from the hole formed by the silicon etching. This allows electrical contact to form when metal is deposited on the back, as shown in FIG. 1(e). In an alternate embodiment, the metal shown in FIG. 1(e) includes a thicker layer of a mechanically strong metal to give the bottom rigidity. For example, the bottom metal could be 2.5 microns of gold, 100 microns of nickel, and another 2.5 microns of gold. This gives excellent conductivity and corrosion resistance to the metal, as well as strong mechanical strength.

The top side masking layer can be patterned at this step, as the front surface of the wafer is still planar and amenable to standard photolithography. In an alternate embodiment, a solder or other bonding material is deposited and patterned in this step, for use with a subsequent wafer bonding process which requires it (not shown in the figure). The wafer is then returned to the anisotropic silicon etch, which undercuts the metal in some places leaving a suspended structure as shown in FIG. 1(f). The masking layer can be etched away at this point (although it is not required), leaving the wafer as it appears in FIG. 1(g). Etching the masking layer will make the suspended metal flatter if the masking layer is grown under stress.

The main wafer is then bonded to the cap wafer, enclosing the suspended metal structure. This bonding is performed using standard wafer bonding techniques, such as thermocompression gold-to-gold bonding. In an alternate embodiment, solder bonding is used with Au/Sn eutectic metal.

FIG. 2 shows examples of filter structures according to the present invention. The metal over the cavity is suspended, while the metal outside the cavity is on top of the wafer. The signal ports shown are coplanar wave guide ports to couple the signal in and out of the filter. Other embodiments have different types of ports, including microstrip, stripline, slot line, and waveguide. FIGS. 2(a) and 2(b) are bandpass filters. These are fabricated as suspended metal lines. In an alternate embodiment, the metal lines are patterned on a thin dielectric membrane. In the embodiment illustrated by FIG. 2(a), the suspended lines form resonators which are grounded at both ends (i.e. connected to the outer shield metal). Typically these are half-wave resonators. For a second order filter, two lines are used. For a Nth order filter, N lines are used. The coupling between two adjacent lines is adjusted by placing the lines closer together or further apart. The coupling is also a function of the relative alignment and offset of the lines. To design a filter to a particular specification, computer simulation is used to determine the strength of coupling between two resonators.

In the example design shown in FIG. 2(a), the input and output ports are coupled to the resonators by a suspended line which connects to the resonator line fairly close to an end of the resonator. Stronger coupling is achieved by contacting the resonator at a point further from the end.

In the example design shown in FIG. 2(b), two wide half-wave resonators are suspended by thin metal lines at each corner. These supporting lines are approximately a quarter wave long at the resonance frequency.

In order to design a filter to a particular specification, standard filter-design techniques are used familiar to those skilled in the art. A common bandpass configuration is to use multiple resonators with a resonant frequency at the center of the desired passband. The coupling factors, which measure the strength of coupling between adjacent resonators and strength of coupling at the input/output are designed to give the desired response using standard filter design techniques, such as Chebychev, Butterworth, or Elliptic designs.

One technique for designing filters, particularly higher order filters, is to make a filter with the correct number of resonators of approximately the correct length and coupling, and to simulate them. The results of such a simulation are compared to a simple linear model consisting of transmission lines and lumped capacitors and inductors. The values of the linear model are adjusted to match the response of a rough three dimensional model. The values of the linear model are then changed to provide the desired filter response. The changes required in the linear model are made to the three dimensional model by adjusting tuning structures and parameters on the three dimensional model. This technique enables the rapid design of a three dimensional, high order filter.

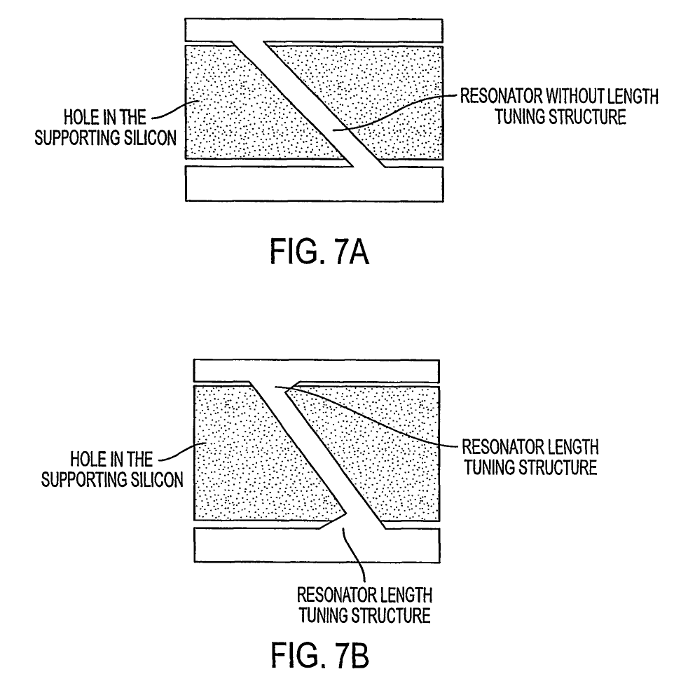

The design technique described above depends on designing and characterizing the tuning structures and parameters that will correspond to changes in a linear model. An example of such a design technique is described below with reference to FIGS. 7(a) and 7(b). FIG. 7(a) shows a resonator without any tuning structure, while FIG. 7(b) shows tuning structures on the end of the resonator. By making these structures larger or smaller, the effective length (and hence resonant frequency) of the resonator can be adjusted without affecting any other part of the device. Changing the width of the pit, for example, would change the effective length of all of the resonators, not just a single one. While this is useful, it would not on it's own provide enough freedom in the tuning. So this tuning structure allows for the resonator length to be modified in a way that is easily characterized in the linear model.

Other design elements that may be modified to change the tuning include changing the angle of the resonators, which can affect the effective length and the coupling. Changing the resonator spacing changes the coupling between two resonators. Modifying the point of contact of the input and output lines, if they in fact contact the resonators, modifies the strength of the coupling to the input and output ports.

The Q of the resonators, and hence the filter performance, is affected by the size of the cavity surrounding the resonators. Generally, larger cavities (produced by fabricating the filters on thicker wafers, or using multi wafer stacks) provide higher Q's for a given frequency. Increasing the vertical dimension of the cavity also increases the coupling between resonators.

Other design features can be used to reduce the sensitivity of the filter to variations in the manufacturing. In one embodiment, the ends of a suspended resonator are flared out where they connect with the metal ground plane. This flaring reduces the sensitivity of the resonant frequency of the resonator to variations in the width of the silicon pit. The cavity in the filter cap can be made wider than the resonators, so as to make contact with the other wafer on the surrounding metal, not near the ends of the resonators. This reduces the sensitivity of the resonant frequency of a resonator to variations in the cap cavity width, as well as misalignment between the cap and the bottom wafer.

FIG. 2(c) cannot be fabricated just as suspended metal, because the stubs would fold over. The embodiment of FIG. 2(c) has the metal on top of a thin dielectric membrane, such as a low stress nitride. The membrane is patterned with small holes in it. The membrane is then undercut by subjecting it first to an isotropic silicon etch, which etches through the holes down and outward, undercutting the membrane. This joins all the holes together by removing the substrate immediately below the membrane, and is followed by an anisotropic silicon etch, which will etch completely through the wafer without etching sideways. The thin dielectric membrane as shown in FIG. 2(c) is made thin enough to not have a significant electromagnetic effect.

An alternative way to undercut a thin dielectric membrane would be to pattern slots in the dielectric that are not aligned to the <110> crystal axis of the silicon. These can be arranged so that anisotropic etching forms a self terminating pit underneath a portion of the dielectric, completely suspending the resonant parts of the filter and maintaining their high Q. An illustration of this is shown in FIG. 2(d).

While a low stress nitride dielectric membrane (such as, for example, a silicon nitride membrane) has been mentioned above, a skilled artisan would readily appreciate that various other dielectric materials may be used without departing from the scope of the present invention.

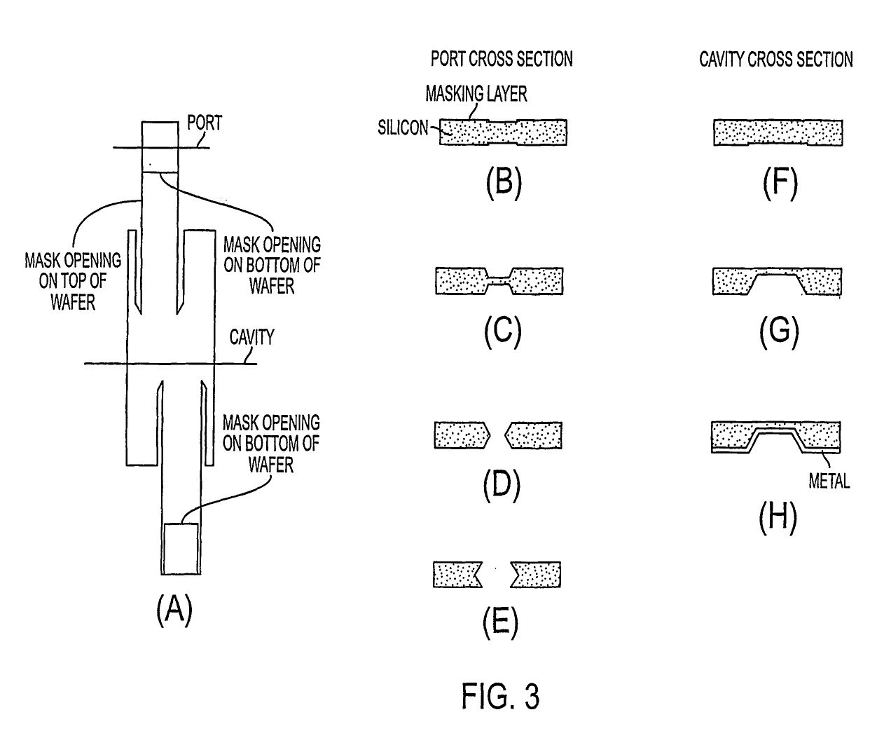

The construction of the cap wafer is now described with reference to FIG. 3.

The cap wafer is fabricated by starting with a wafer of <100> high resistivity silicon with a masking layer deposited or grown on both sides. The masking layer is patterned on both sides of the wafer. An example of a pattern for the opening in the mask is shown in FIG. 3(a). The wafer is then etched in an anisotropic silicon etch. Where a cap which is not fully etched through the wafer is desired, the masking layer is patterned only on one side. Where a through hole is desired, the masking layer is patterned on both sides, and the pits meet in the middle during the etching process. A cross section of a port (or access hole) is shown in FIGS. 3(b) through (e). FIG. 3(b) shows the initial mask layer. FIG. 3(c) shows the wafer part of the way through the silicon etch. FIG. 3(d) shows the wafer just as the two pits meet. FIG. 3(e) shows the final cross section achieved if the etch is left to continue for a long time.

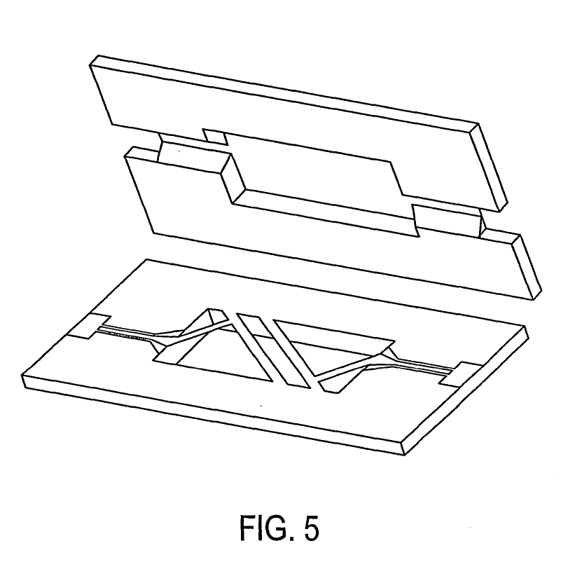

FIGS. 3(f) through (h) show the fabrication of the cap section. FIG. 3(g) shows the profile after etching is completed. After the etching is completed, the masking layer is removed, and metal is deposited on one side. FIG. 5 shows a cap section and the corresponding main wafer section.

The cap wafer is made by patterning the masking layer on both sides of the wafer. This is done using standard photolithographic and etching techniques. For example, one embodiment has a masking layer of thermally grown silicon dioxide which is etched with 10% hydrofluoric acid buffered oxide etch. The wafer is etched in an anisotropic silicon etch. One example of such an etch is 25% weight/weight tetra methyl ammonium hydroxide and water heated to 95 degrees Celsius. In order to provide a cavity of the correct shape, convex corner protectors are needed to protect the convex corners of the mask from being undercut. An example of a cap wafer pattern is shown in FIG. 3. FIG. 3(a) shows the initial mask pattern. FIG. 3(b) shows the silicon surface after etching for some period of time. FIG. 3(c) shows the cap layer at the completion of etching, after the convex corner protector has been completely consumed. FIG. 3(d) shows the rounding of the convex corners after etching past the completion time.

The cap wafer is etched only partly through the wafer. This is done by timing the etch and stopping it when the appropriate etch depth is reached. An alternate method uses an etch stop layer in the wafer, for example a buried oxide layer in a silicon on insulator wafer. A silicon on insulator wafer is a silicon wafer with an oxide layer buried underneath the silicon on one side. They can be formed by a variety of methods, including bonding two silicon wafers together after growing an oxide on them, and polishing away one wafer until the silicon over the insulator reaches the desired thickness.

For the example of a cap wafer formed by timing the etch, the convex corner protectors need to be calibrated so that the etch depth of the cap wafer cavity is reached at the same time the convex corner protectors are completely consumed.

The cap wafer needs holes all the way through the wafer in some places to allow electrical connections to be made to the filter. In the case of the cap wafer formed by timing the etch, this can be accomplished by patterning the masking layer on the other side of the cap wafer. The holes from the two sides will meet in the middle, forming a hole completely through the wafer. This process is illustrated in FIG. 3. FIG. 3(a) shows the initial holes patterned in the masking layer on the top and bottom of the wafer. A cross section showing the etched port as it etches is shown in FIGS. 3(b) through 3(e). FIG. 3(b) shows the wafer before etching. FIG. 3(c) shows the wafer after etching for less than half the wafer thickness. FIG. 3(d) shows the wafer just as the holes from either side meet. FIG. 3(e) shows the final shape of the cross section of the hole through the wafer, if the etch is allowed to proceed indefinitely.

The cavity body itself is shown in cross section if FIGS. 3(f) through 3(h). FIG. 3(f) shows the initial mask. FIG. 3(g) shows the wafer after the completion of the timed etch. FIG. 3(h) shows the wafer after metal has been deposited. The metal is deposited using some standard technique. For example, a seed layer of chrome and gold can be evaporated on the wafer, followed by a gold electroplating step.

An alternate method of forming the cap layer is to etch using a dry etching technique, such as deep reactive ion etching. There are reactive ion etching techniques available which can etch the cavity without the need for convex corner protectors.

Finally, the cap wafer and the main wafer are brought together and bonded. The bonding can be accomplished in many ways. One method is to electroplate Tin-Lead solder in selected regions of the main wafer, and bring the wafers into contact and heat them under pressure to reflow the solder. Other techniques include gold to gold thermocompression bonding, the use of other solders, or the deposition of other materials which will form a eutectic when heated.

FIG. 1(h) shows the cross section of a device with the cap wafer and the main wafer bonded together. The suspended metal structure is now completely enclosed in metal, except for the input and output ports. The bonded wafers are diced using standard silicon dicing techniques. FIG. 5 shows the top and bottom of a final device. Note that the devices are bonded together at the wafer level. This eases the bonding process, because bonding alignment marks can be patterned in unused sections of the wafer. It also allows one alignment and bonding step to bond all the devices on a wafer.

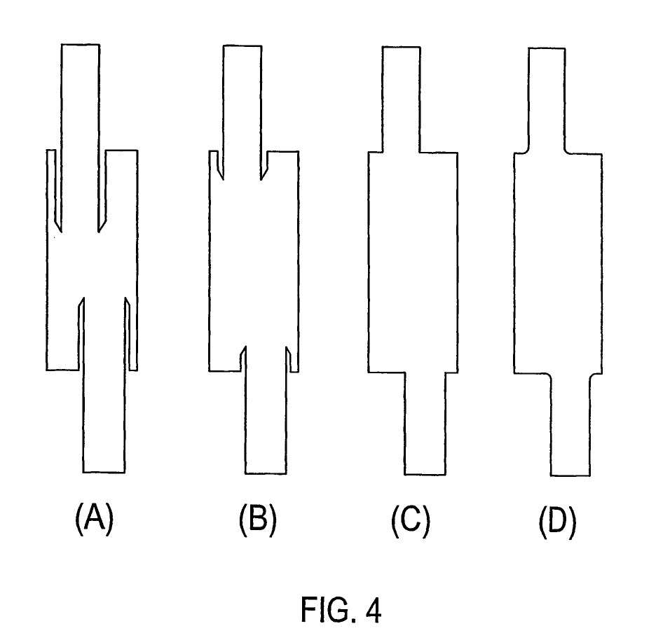

Convex corner protectors for the cap wafer layer are illustrated in FIG. 4.

The mask opening pattern for the cap for many designs has features that end up as convex corners. FIG. 4(a) shows the initial masking layer with convex corner protectors. FIG. 4(b) shows the surface of the silicon during the etch, with the convex corners partially consumed. By calibrating the convex corner protectors properly, they can be designed so they will be completely consumed just when the cavity reaches its target depth. This is shown in FIG. 4(c). If the wafer is etched more, the convex corners get rounded, as shown in FIG. 4(d).

An exploded view of a device according to an embodiment of the present invention is shown in FIG. 5.

This figure illustrates the final device. The signal ports are to the left and the right. Note the access holes in the cap layer which allow access to the signal port lines from the top. This allows for wiring bonding or probing of the device.

The filter and cap are bonded in batch as complete wafers, before being cut up into individual devices. This simplifies alignment (because bonding alignment marks can be put in an unused section of the wafers), and reduces the labor of aligning and bonding. A pair of wafers, the first containing an array of filters, and the second containing a corresponding array of caps, are aligned and bonded to each other by the solder bonding process described above, or by an alternate process. In solder bonding, the wafers are aligned in a fixture which allows the wafers to be clamped together in precise alignment, and then they are heated to above the eutectic temperature of the solder while clamped in an inert atmosphere such as 5% Hydrogen, 95% nitrogen, etc. achieve bonding. Finally, the individual devices are separated by a standard semiconductor dicing saw.

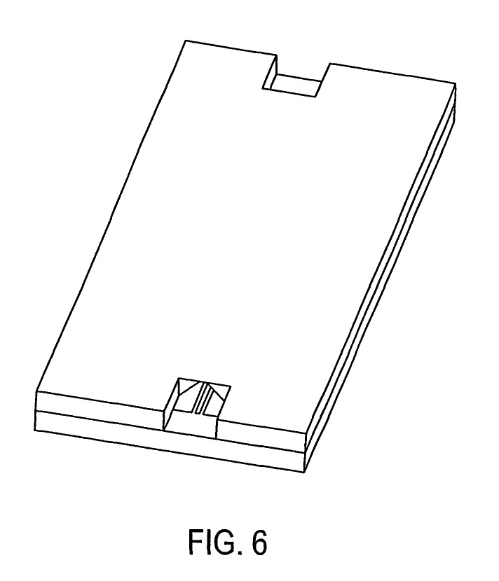

FIG. 6 shows an example of a final bonded device after the wafer has been diced.

When the device is completed, only the signal ports are visible from the outside. The suspended metal structures are enclosed in metal. The bottom is covered in metal, which facilitates the attachment of the device to a substrate or block. This bottom metal is connected electrically to the metal border which surrounds the suspended metal structure. Together, these form a ground shield which fully surrounds the resonators (except at the ports).

In an alternate embodiment, the metal-filled pits which connect the ground planes on the top and bottom side of the main wafer is not a long, continuous groove, but is rather a series of individual via holes. This allows the pits to be of more uniform size, allowing higher yield. In this case, the grounding is achieved by a series of via holes, a technique which is commonly understood by those skilled in the art.

One of the key elements of a filter design in accordance with a particularly advantageous embodiment of the invention, is that the filter is fully enclosed and shielded, except for the input and output ports. That is, the resonators are enclosed in metal (see FIG. 6). This is useful because it prevents losses and performance degradation due to radiation, and it prevents unwanted interference between the filter and other parts of the circuit.

While various implementations and methods of manufacturing filters according to the present invention have been described in detail, a skilled artisan will readily appreciate that numerous other implementations and variations of the filter design are possible without departing from the spirit of the invention. Accordingly, the scope of the invention is defined by the claims set forth below.

We claim:

1. A microwave/millimeter wave filter comprising:
a suspended metal structure; and
ports for coupling a signal to said suspended metal structure.

2. A method of manufacturing a microwave/millimeter wave filter comprising:
forming a metal structure on a wafer; and
removing a portion of said wafer under at least a portion of said metal structure thereby suspending said portion of said metal structure.

3. A computer readable memory storing a control program for controlling manufacturing of microwave/millimeter wave filter, the control program comprising the functions of:
performing three dimensional electromagnetic simulation to generate design parameters for microwave/millimeter wave filter structures on a substrate; and
generating graphical data files based on said design parameters, said graphical data file representing at least one image for at least one photomask for performing micromachining processing based on said design parameters to remove a portion of said substrate and form a suspended metal structure which constitutes said microwave/millimeter wave filter.

4. An electronic circuit board comprising:
a microwave/millimeter wave filter which has a suspended metal structure and ports for coupling a signal to said suspended metal structure; and
an electrical connection coupled to at least one of said ports.

5. The microwave/millimeter wave filter as claimed in claim 1 further comprising:
a first layer which includes said suspended metal structure; and
a second layer which has a cavity formed therein, said second layer is positioned above said first layer with said cavity facing said suspended metal structure.

6. The microwave/millimeter wave filter as claimed in claim 5 wherein said first layer is bonded to said second layer, whereby said suspended metal structure is enclosed within said first and second layers, and said ports are constituted by exposed connections to said suspended metal structure.

7. The microwave/millimeter wave filter as claimed in claim 5, wherein said second layer further comprises dicing marks and access holes.

8. The microwave/millimeter wave filter as claimed in claim 5 further comprising at least one RF transmission line leading to said metal structure.

9. The microwave/millimeter wave filter as claimed in claim 1, wherein said suspended metal structure comprises coupled resonators.

10. The method of manufacturing a microwave/millimeter wave filter as claimed in claim 2, wherein said forming said metal structure comprises forming a patterned layer of a first metal on a front side of said wafer, said method further comprising:
removing a first portion of said wafer to expose a first portion of said first metal; and
coating a backside of said wafer with a second metal, said second metal forming a contact with-said first portion of said first metal; and
wherein said removing said portion of said wafer comprises removing a second portion of said wafer to undercut at least a second portion of said first metal thereby suspending said portion of said first metal.

11. The method of manufacturing a microwave/millimeter wave filter as claimed in claim 2, further comprising forming a masking layer on a front side and on a back side of said wafer, said metal being formed on said front side of said masking layer.

12. The method of manufacturing a microwave/millimeter wave filter as claimed in claim 11, wherein said masking layer is a silicon dioxide layer.

13. The method of manufacturing a microwave/millimeter wave filter as claimed in claim 11, wherein said masking layer comprises a dielectric membrane under said suspended portion of said metal structure.

14. The method of manufacturing a microwave/millimeter wave filter as claimed in claim 2, further comprising:
forming a cavity in a second wafer; and
placing said second wafer on said wafer having said metal structure in alignment and over said suspended portion of said metal structure.

15. The method of manufacturing a microwave/millimeter wave filter as claimed in claim 14, further comprising, prior to said placing:
forming through holes in said second wafer, said through holes constituting access ports to said suspended portion of said metal structure; and
forming a metal layer on a surface of said second wafer, said surface having a cavity formed therein, said metal layer extending along at least a portion of said cavity.

16. The method of manufacturing a microwave/millimeter wave filter as claimed in claim 15, further comprising bonding said wafer having said metal structure and said second wafer.

17. The method of manufacturing a microwave/millimeter wave filter as claimed in claim 15, wherein forming said metal structure comprises forming isolated metal portions extending from said suspended portion, said isolated metal portions being exposed via said through holes.

18. The method of manufacturing a microwave/millimeter wave filter as claimed in claim 13, wherein said dielectric membrane is a low stress silicon nitride film.

19. The microwave/millimeter wave filter as claimed in claim 5 further comprising at least one coplanar waveguide line leading to said metal structure.

20. The microwave/millimeter wave filter as claimed in claim 8, wherein said RF transmission line is any one of a waveguide, a stripline, a slotline, or a microstrip.

21. The microwave/millimeter wave filter as claimed in claim 1, wherein said suspended metal structure is enclosed by a metal with said ports being exposed.

22. The method of manufacturing a microwave/millimeter wave filter as claimed in claim 2, further comprising enclosing said suspended metal structure by a metal and leaving exposed access ports to said suspended metal structure.

23. The method of manufacturing a microwave/millimeter wave filter as claimed in claim 10, further comprising:
forming a cavity in a second wafer;
forming through holes in said second wafer, said through holes constituting access ports to said suspended portion of said metal structure;
forming a third metal layer on a surface extending along at least a portion of said cavity in said second layer;
placing said second wafer on said wafer having said metal structure, in alignment and over said suspended portion of said metal structure; and
bonding said second wafer and said wafer to enclose said suspended portion of said metal structure within said second metal and said third metal, and to expose said access ports.

24. The electronic circuit board as claimed in claim 4, wherein said suspended metal structure is enclosed by a metal and said ports are exposed for coupling said electrical connection to at least one of said ports.

25. A method of designing a micromachined filter having a desired response characteristic associated therewith, said method comprising:
generating a first model of said filter, said first model comprising:
at least one first parameter, and
a first modeled response characteristic, which is a function at least of said first parameter, as an output thereof;
generating a second model of said filter, said second model comprising:
at least one second parameter, and
a second modeled response characteristic, which is a function at least of said second parameter, as an output thereof;
adjusting said second parameter to match said second modeled response characteristic to said first modeled response characteristic;
further adjusting said second parameter to match said second modeled response characteristic to said desired response characteristic; and
adjusting said first parameter in accordance with said further adjusting of said second parameter, thereby obtaining adjusted first parameters which result in matching said first modeled response characteristic to said desired response characteristic.

26. The method of designing a micromachined filter as claimed in claim 25, wherein said adjusting said second parameter, said further adjusting said second parameter, and said adjusting said first parameter are iterated until said first modeled response characteristic matches said desired response characteristic.

27. The method of designing a micromachined filter as claimed in claim 25, further comprising a plurality of first parameters, said first modeled response characteristic being a function of said plurality of first parameters.

28. The method of designing a micromachined filter as claimed in claim 27, further comprising a plurality of second parameters, said second modeled response characteristic being a function of said plurality of second parameters.

29. The method of designing a micromachined filter as claimed in claim 25, wherein said first model of said filter is a three-dimensional model of said filter.

30. The method of designing a micromachined filter as claimed in claim 29, wherein said second model of said filter is a linear model of said filter.

31. The method of designing a micromachined filter as claimed in claim 30, wherein said first parameter is representative of a structure of said filter.

32. The method of designing a micromachined filter as claimed in claim 31, wherein said first parameter is number of resonators of said filter, said first model of said filter further comprising lengths of said resonators as additional first parameters.

33. The method of designing a micromachined filter as claimed in claim 32, wherein said second parameter is a tuning parameter of said filter.

34. The method of designing a micromachined filter as claimed in claim 33, wherein said second model of said filter further comprises additional tuning parameters of said filter.

35. The method of designing a micromachined filter as claimed in claim 34, wherein said tuning parameter or said additional tuning parameters are any of: an orientation angle of at least one of said resonators; a length of at least one of said resonators; spacing of said resonators; or at least one dimension of a cavity having said resonators disposed therein.

36. The method of designing a micromachined filter as claimed in claim 25, wherein said filter comprises a suspended metal structure, and ports for coupling a signal to said suspended metal structure; and
wherein said desired response characteristic is a function of parameters associated with said suspended metal structure.
